(19) United States
(12) Patent Application Publication
(10) Pub. No.: US 2009/0241834 A1
(43) Pub. Date: Oct. 1, 2009

(54) SUBSTRATE PROCESSING APPARATUS

(75) Inventor: Tsutomu KATO, Takaoka-shi (JP)

Correspondence Address: MATTINGLY & MALUR, P.C., 1800 DIAGONAL ROAD, SUITE 370, ALEXANDRIA, VA, 22314, US

(73) Assignee: Hitchi Kokusai Electric, Inc.

(21) Appl. No.: 12/393,123

(22) Filed: Feb. 26, 2009

(30) Foreign Application Priority Data
Apr. 1, 2008 (JP) 2008-095410
Nov. 5, 2008 (JP) 2008-284589

(51) Int. Cl. C23C 16/44

(52) U.S. Cl. 118/715

(57) ABSTRACT

A substrate processing apparatus comprises: a processing chamber configured to accommodate a substrate; and a gas supply unit configured to supply gas into the process chamber. The gas supply unit comprises: an evaporator configured to evaporate a liquid material; a first gas supply pipe configured to supply an evaporated gas from the evaporator into the process chamber; a second gas supply pipe configured to supply an inert gas into the process chamber; and a joint part at which the first gas supply pipe and the second gas supply pipe are joined. The joint part includes a diffusion chamber. A flow rate diaphragm having an inner diameter narrowing toward a direction of the diffusion chamber is installed at the front end of the downstream side of the second gas supply pipe. The evaporated gas from the evaporator is introduced into the diffusion chamber and simultaneously the inert gas is introduced through the flow rate diaphragm installed at the front end of the second gas supply pipe.

### CROSS-REFERENCE TO RELATED PATENT APPLICATION

This U.S. non-provisional patent application claims priority under 35 U.S.C. §119 of Japanese Patent Application Nos. 2008-095410, filed on Apr. 1, 2008, and 2008-284589, filed on Nov. 5, 2008, in the Japanese Patent Office, the entire contents of which are hereby incorporated by reference.

### BACKGROUND OF THE INVENTION

1. Field of the Invention

The present invention relates to a substrate processing apparatus which manufactures a semiconductor device by performing a variety of processes such as formation of thin films, diffusion of impurities, etching, or annealing on a substrate such as a silicon wafer.

2. Description of the Prior Art

A substrate processing apparatus for manufacturing a semiconductor device includes a process furnace which accommodates a substrate such as a silicon wafer in a process chamber and processes the substrate by heating the substrate and introducing a process gas into the process chamber.

The process gas includes an evaporated gas generated by evaporating a liquid state material at a predetermined temperature. The evaporated gas joins with a purge gas and supplied into the process chamber.

FIG. 6 schematically illustrates a process furnace. A reference numeral 1 represents a process tube defining a process chamber 2, and a reference numeral 3 represents a gas nozzle through which a process gas is supplied into the process chamber 2. A gas supply pipe 4 is connected to the gas nozzle 3. A substrate loaded into the process chamber 2 is not shown in the drawing.

The gas supply pipe 4 is connected through a valve 5 to an inert gas supply source (not shown) such as nitrogen gas. In addition, a process gas supply pipe 6 is connected to the gas supply pipe 4, and an evaporator 8 is connected through an on/off valve 9 to the process gas supply pipe 6.

The process gas evaporated by the evaporator 8 passes through the process gas supply pipe 6 and joins in the gas supply pipe 4. Then, the evaporated process gas is supplied from the gas nozzle 3 to the process chamber 2, together with the inert gas supplied as a carrier gas through the gas supply pipe 4. Furthermore, in order to purge the inside of the process gas supply pipe 6 after the process, the gas inside the process gas supply pipe 6 is replaced with the inert gas by circulating the inert gas from the gas supply pipe 4 to the process gas supply pipe 6 when the on/off valve 7 is in a closed state.

A joint part 12 of the gas supply pipe 4 and the process gas supply pipe 6 will be described with reference to FIG. 7. In FIG. 7, a reference numeral 11 represents a 3-way valve 11 including the on/off valve 7 and the on/off valve 9.

The gas supply pipe 4 is connected perpendicular to an outlet of the 3-way valve 11 of the process gas supply pipe 6, and the joint part 12 is formed in a T shape.

When purging the process gas supply pipe 6, as described above, if the inert gas is supplied from the gas supply pipe 4 to the process gas supply pipe 6, the inert gas collides with the process gas supply pipe 6 so that its flow direction is changed, and most of the inert gas flows in a direction from the process gas supply pipe 6 to the process chamber 2. Moreover, some of the inert gas collides with the process gas supply pipe 6 and flows toward the 3-way valve 11. Therefore, a region between the 3-way valve 11 and the joint part 12 becomes a dead space 13, and the process gas is sealed in the dead space 13.

Therefore, the process gas remains in the dead space 13, and the remaining gas is liquefied or pyrolyzed so that it becomes a cause of particles. Furthermore, if the wafer is contaminated by particles, quality is deteriorated and yield is decreased.

Moreover, in case where the inert gas is supplied as the carrier gas, if the flow rate of the carrier gas increases, pressure inside the process gas supply pipe 6 increases, which will increase pressure of an evaporation chamber of the evaporator and degrade evaporation performance.

[Patent Document 1] Patent Publication No. 2006-269646

### SUMMARY OF THE INVENTION

Therefore, an object of the present invention is to eliminate a dead space in a joint part of a process gas supply pipe and a purge gas supply pipe, to prevent generation of particles, and to suppress the increase of pressure inside the purge gas supply pipe and the degradation of evaporation performance of an evaporator.

According to an aspect of the present invention, there is provided a substrate processing apparatus, comprising: a processing chamber configured to accommodate a substrate; and a gas supply unit configured to supply gas into the process chamber, wherein the gas supply unit comprises: an evaporator configured to evaporate a liquid material; a first gas supply pipe configured to supply an evaporated gas from the evaporator into the process chamber; a second gas supply pipe configured to supply an inert gas into the process chamber; and a joint part at which the first gas supply pipe and the second gas supply pipe are joined, wherein the joint part has a diffusion chamber; a flow rate diaphragm having an inner diameter narrowing toward a direction of the diffusion chamber is installed at the front end of the downstream side of the second gas supply pipe; and the evaporated gas from the evaporator is introduced into the diffusion chamber and simultaneously the inert gas is introduced through the flow rate diaphragm installed at the front end of the second gas supply pipe.

According to another aspect of the present invention, there is provided a substrate processing apparatus, comprising: a processing chamber configured to accommodate a substrate; and a gas supply unit configured to supply gas into the process chamber, wherein the gas supply unit comprises: a first gas supply pipe configured to supply a process gas; a second gas supply pipe configured to supply a purge gas for purging at least the first gas supply pipe; and a joint part at which the first gas supply pipe, the second gas supply pipe and the third gas supply pipe are joined at a predetermined angle, wherein the joint part includes a diffusion chamber; a diaphragm having an inner diameter narrowing toward a direction of the diffusion chamber is installed at the front end of a downstream side of the second gas supply pipe; an inner diameter of a flow path penetrating the diaphragm is smaller than that of the second gas supply pipe; the purge gas is sprayed into the diffusion chamber through the flow path and is exhausted from the third gas supply pipe while sucking a residual process gas remaining in the joint part.

### BRIEF DESCRIPTION OF THE DRAWINGS

FIG. 1 is a schematic perspective view of a substrate processing apparatus relevant to an embodiment of the present invention.

FIG. 2 is a schematic sectional view of a substrate process furnace used in the substrate processing apparatus.

FIG. 3 is a sectional view taken in an arrow direction A-A of FIG. 2.

FIG. 4 is a view of a gas joint part in the substrate processing apparatus.

FIG. 5 is an enlarged view of the gas joint part.

FIG. 6 is a schematic view for explaining a conventional substrate processing apparatus.

FIG. 7 is a view of a conventional gas joint part.

### DETAILED DESCRIPTION OF THE PREFERRED EMBODIMENTS

Hereinafter, preferred embodiments will be described with reference to the attached drawings.

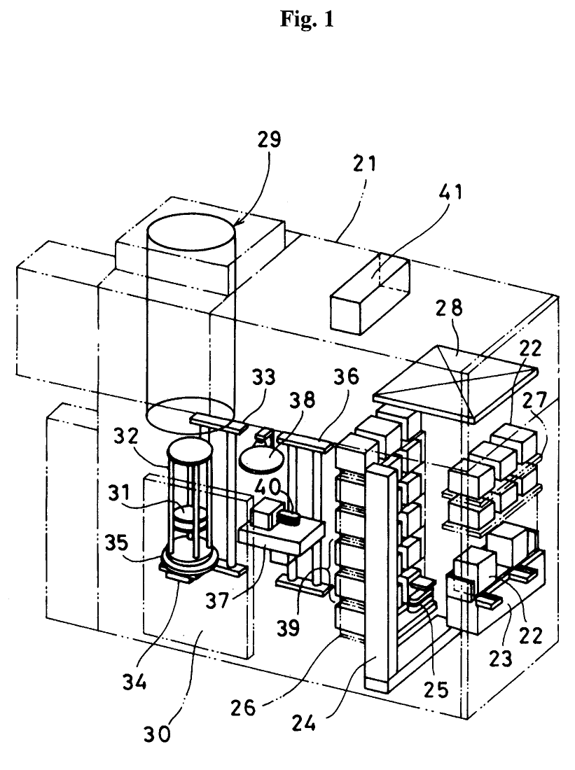

FIG. 1 illustrates an example of a substrate processing apparatus according to the present invention.

First, a substrate processing apparatus according to the present invention will be schematically described.

At the front side of the inside of a housing 21, a cassette stage 23 is installed as a container delivery means for giving and receiving cassettes 22 as a substrate container to/from an external transfer device (not shown). At the rear side of the cassette stage 23, a cassette elevator 24 is installed as an elevating means. At the cassette elevator 24, a cassette transfer device 25 is installed as a cassette transfer means. Furthermore, at the rear side of the cassette elevator 24, a cassette shelf 26 is installed as a cassette accommodating means. At the upward part of the cassette stage 23, a standby cassette shelf 27 is installed as a cassette accommodating means. At the upward part of the standby cassette shelf 27, a clean unit 28 configured by a fan and a dust-proof filter is installed so that clean air is circulated through the inside of the housing 21, for example, a region where the cassettes 22 are transferred.

At the rear upward part of the housing 21, a substrate process furnace 29 is installed. At the downward part of the substrate process furnace 29, a boat elevator 33 is installed an elevating means and configured so that a boat 32 being a substrate holding means for holding wafers 31 as substrates horizontally in multiple stages is loaded into or unloaded from the substrate process furnace 29. At the front end of an elevating member 34 installed at the boat elevator 33, a seal cap 35 as a lid is installed to cover a furnace throat part of the substrate process furnace 29. The boat 32 is vertically supported on the seal cap 35, and the boat 32 holds the wafers 31 horizontally in multiple stages.

A transfer elevator 36 as an elevating means is installed between the boat elevator 33 and the cassette shelf 26, and a wafer transfer device 37 as a substrate transfer means is installed at the transfer elevator 36. The wafer transfer device 37 includes predetermined sheets (for example, 5 sheets) of substrate transfer plates 40 for loading the substrates, and the substrate transfer plates are configured to be movable forward and backward and rotatable.

In the vicinity of the lower part of the substrate process furnace 29, a furnace throat shutter 38 is installed as a sealing member which has an opening/closing mechanism and closes the furnace throat of the substrate process furnace 29.

At the side of the housing 21 facing the transfer elevator 36, a clean unit 30 configured by a fan and a dust-proof filter is installed, and clean air blown from the clean unit 30 is circulated through a region including the wafer transfer device 37, the boat 32 and the boat elevator 33, and is exhausted to the outside of the housing 21 by an exhaust device (not shown).

The driving control of the cassette transfer device 25, the wafer transfer device 37 and the boat elevator 33, the heating control of the substrate process furnace 29, and the like are performed by the control unit 41.

The operation will be described hereinafter.

The cassettes 22 charged with the wafers 31 at the horizontal position are transferred from an external transfer device (not shown) to the cassette stage 23 and are rotated 90 degrees at the cassette stage 23 such that the wafers 31 are placed at the horizontal position. Furthermore, the cassettes 22 are transferred from the cassette stage 23 to the cassette shelf 26 or the standby cassette shelf 27 in cooperation with the elevating and transverse motion of the cassette elevator 24 and the forward-backward-rotating motion of the cassette transfer device 25.

At the cassette shelf 26, a transfer shelf 39 is installed to accommodate the cassettes 22 to be carried by the wafer transfer device 37, and the cassettes 22 charged with the wafers 31 are transferred to the transfer shelf 39 by the cassette elevator 24 and the cassette transfer device 25.

When the cassettes 22 are delivered to the transfer shelf 39, the wafer transfer device 37 delivers the wafers 31 from the transfer shelf 39 to the downward-moving boat 32 in cooperation with the forward-backward-rotating motion of the substrate transfer plate 40 and the elevating motion of the transfer elevator 36.

When predetermined sheets of the wafers 31 are transferred to the boat 32, the boat 32 is moved upward by the boat elevator 33 and the boat 32 is loaded into the substrate process furnace 29. When the boat 32 is completely loaded, the substrate process furnace 29 is air-tightly sealed by the seal cap 35.

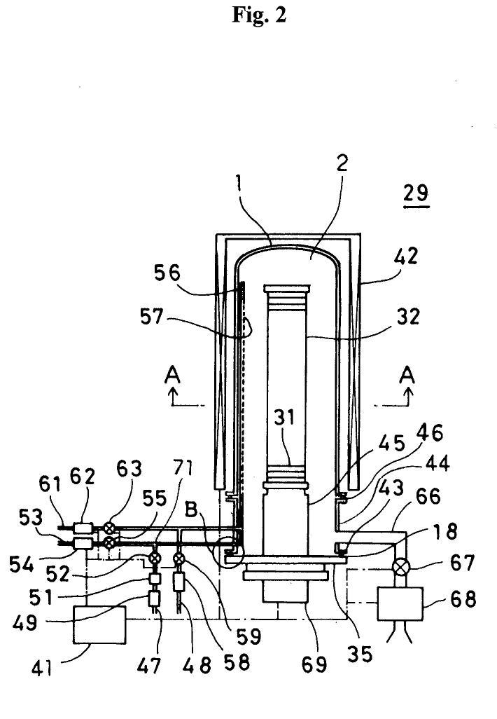

At the inside of the air-tightly sealed substrate process furnace 29, the wafers 31 are heated and simultaneously the process gas is supplied into the substrate process furnace 29 according to a selected process recipe, so that the processing of the wafers 31 is performed by exhausting atmosphere of the process chamber 2 from a gas exhaust pipe 66 by an exhaust device (not shown) (see FIG. 2).

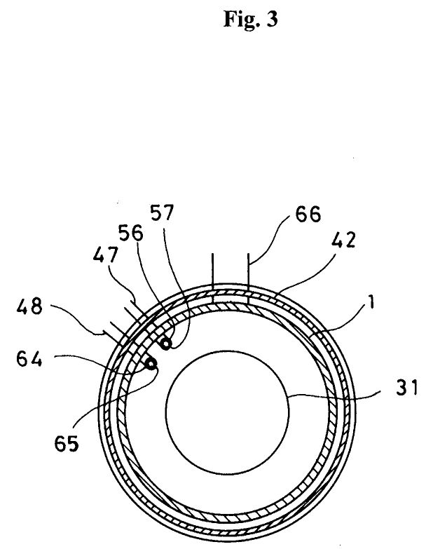

A vertical type substrate process furnace 29 used in the substrate processing apparatus will be described with reference to FIG. 2 and FIG. 3. In addition, like reference numerals are used to refer to like elements throughout FIG. 2, FIG. 3 and FIG. 6.

A reaction tube 1 is installed inside a heater 42 which is a heating device (heating unit). At the lower part of the reaction tube 1, a manifold 44 made of a material such as stainless steel is connected through an O-ring 46 being a sealing member, and a lower opening (furnace throat part) of the manifold 44 is air-tightly sealed through an O-ring being a sealing member by the seal cap 35 being a lid. The process chamber 2 is defined at least by the reaction tube 1, the manifold 44 and the seal cap 35.

At the seal cap 35, the boat 32 is erected through a boat support 45, and the boat support 45 acts as a holder for holding the boat 32.

In the process chamber 2, two gas supply pipes (first gas supply pipe 47 and second gas supply pipe 48) are installed as supply paths to supply a plurality of kinds of process gases, in this case, two kinds of process gases.

At the first gas supply pipe 47, a liquid mass flow controller 49 being a flow rate control device (flow rate control means), an evaporator 51, a first valve 52 being an on/off valve are sequentially installed from the upstream side. At the downstream side of the first valve 52, a first carrier gas supply pipe 53 to supply a carrier gas is joined. At the first carrier gas supply pipe 53, a second mass flow controller 54 being a flow rate control device (flow rate control means) and a third valve 55 being an on/off valve are sequentially installed from the upstream side. Furthermore, at the front end of the first gas supply pipe 47, a first nozzle 56 is installed from the lower part to the upper part along inner walls of the reaction tube 1, and first gas supply holes 57 supplying gas are installed at the side of the first nozzle 56. The first gas supply holes 57 are installed at the same pitches from the lower part to the upper part and have the same opening area.

At the second gas supply pipe 48, a first mass flow controller 58 being a flow rate control device (flow rate control means) and a second valve 59 being an on/off valve are sequentially installed from the upstream direction, and a second carrier gas supply pipe 61 supplying a carrier gas is joined at the downstream side of the second valve 59. At the second carrier gas supply pipe 61, a third mass flow controller 62 being a flow rate control device (flow rate control means) and a fourth valve 63 being an on/off valve are sequentially installed from the upstream side. At the front end of the second gas supply pipe 48, a second nozzle 64 is installed in parallel to the first nozzle 56, and second gas supply holes 65 supplying gas are installed at the side of the second nozzle 64. The second gas supply holes 65 are installed at the same pitches from the lower part to the upper part and have the same opening area.

For example, when a source material supplied from the first gas supply pipe 47 is a liquid, the liquid is supplied from the first gas supply pipe 47 through the liquid mass flow controller 49, the evaporator 51 and the first valve 52 and is jointed with the first carrier supply pipe 53, and the process gas is supplied into the process chamber 2 through the first nozzle 56. For example, when a source material supplied from the first gas supply pipe 47 is a gas, the liquid mass flow controller 49 is replaced with a gas mass flow controller and the evaporator 51 is unnecessary. The gas is supplied from the second gas supply pipe 48 through the first mass flow controller 58 and the second valve 59 and is joined with the second carrier gas supply pipe 61, and the process gas is supplied into the process chamber 2 through the second nozzle 64.

The process chamber 2 is connected to a vacuum pump 68 as an exhaust device (exhaust means) through a fifth valve 67 by the gas exhaust pipe 66 exhausting the gas, so that the process chamber 2 is vacuum-exhausted. Furthermore, the fifth valve 67 is an on/off valve which can be opened/closed to perform the vacuum exhaust of the process chamber 2 and stop the vacuum exhaust of the process chamber 2 and can adjust pressure by controlling opening degree of the valve.

At the seal cap 35, a boat rotating mechanism 69 is installed to rotate the boat 32 in order to enhance the processing uniformity.

The controller 41 as a control means is connected to the liquid mass flow controller 49, the first to third mass flow controllers 58, 54 and 62, the first to fifth valves 52, 59, 55, 63 and 67, the heater 42, the vacuum pump 68, the boat rotating mechanism 69, and a boat elevating mechanism (not shown), and performs the flow rate control operation of the liquid mass flow controller 49 and the first to third mass flow controllers 58, 54 and 62, the opening/closing operation of the first to fourth valves 52, 59, 55 and 63, the opening/closing and pressure control operation of the fifth valve 67, the temperature control operation of the heater 42, the start and stop operation of the vacuum pump 68, the rotation speed control operation of the boat rotating mechanism 69, and the elevating operation control of the boat elevating mechanism.

Next, explanation will be made on an example of a film forming process using an Atomic Layer Deposition (ALD) method, specifically, an example of forming an HfO₂ film using TEMAH (tetrakis(ethylmethylamino)hafnium) and O₃, which is one of semiconductor device fabrication processes.

The ALD method as a kind of a Chemical Vapor Deposition (CVD) method is technology which supplies at least two kinds of reactive gases alternately under the film forming conditions (temperature, time, and the like), in order for the substrate to adsorb the source gases with atomic unit and form the film through surface reaction. In this case, the control of film thickness is performed by number of cycles of supplying the reactive gases (for example, assuming that a film forming speed is 1 Å/cycle, 20 cycles are executed in order to form a film of 20 Å).

In the ALD method, when the HfO₂ film is formed, a high-quality film can be formed at a low temperature of 180-250° C. by using TEMAH (Hf[NCH₃C₂H₅]₄, tetrakis(ethylmethylamino)hafnium) and O₃ (ozone).

First, as described above, the wafers 31 are charged into the boat 32 and loaded into the process chamber 2. After loading the boat 32 into the process chamber 2, the following four steps are sequentially executed.

(Step 1)

In the step 1, TEMAH and carrier gas (N₂) are supplied. The first valve 52 installed in the first gas supply pipe 47, the third valve 55 installed in the first carrier gas supply pipe 53, and the fifth valve 67 installed in the gas exhaust pipe 66 are all opened so that the flow rate is controlled by the first gas supply pipe 47 and the liquid mass flow controller 49. Thus, the TEMAH gas evaporated by the evaporator 51 is mixed with the carrier gas (N₂) whose flow rate is controlled by the first carrier gas supply pipe 53 and the second mass flow controller 54, and the mixed gas is supplied from the first gas supply holes 57 of the first nozzle 56 into the process chamber 2 and is exhausted through the gas exhaust pipe 66. The supply flow rate of the TEMAH gas controlled by the liquid mass flow controller 49 is 0.1-0.3 g/min. The exposure time of the wafers 31 to the TEMAH gas is 30-180 seconds. In this case, the temperature of the heater 42 is set so that the wafers 31 have a temperature of 180-250° C. Furthermore, pressure inside the process chamber 2 is 50-100 Pa. Therefore, the TEMAH material is adsorbed on a basic layer of the wafer 31.

(Step 2)

In the step 2, the first valve 52 of the first gas supply pipe 47 and the third valve 55 of the first carrier supply pipe 53 are closed to stop supplying the TEMAH gas and the carrier gas. The fifth valve 67 of the gas exhaust pipe 66 is maintained in an open state, and the substrate process furnace 29 is exhausted to below 20 Pa by the vacuum pump 68, and the remaining TEMAH gas is removed from the inside of the process chamber 2. Furthermore, in this case, if inert gas, for example N₂ used as the carrier gas is supplied into the substrate process furnace 29, the effect of removing the TEMAH gas is further enhanced.

(Step 3)

In the step 3, O₃ and carrier gas (N₂) are supplied. First, the second valve 59 installed in the second gas supply pipe 48 and the fourth valve 63 installed in the second carrier gas supply pipe 61 are all opened so that O₃ supplied from the second gas supply pipe 48 and having the flow rate controlled by the first mass flow controller 58 is mixed with the carrier gas (N₂) supplied from the second carrier gas supply pipe 61 and having the flow rate controlled by the third mass flow controller 62. Then, the mixed gas is supplied from the second gas supply holes 65 of the second nozzle 64 into the process chamber 2 and is exhausted from the gas exhaust pipe 66. The exposure time of the wafers 31 to O₃ is 10-120 seconds. In this case, the temperature of the wafers 31 is 180-250° C. which is the same as in the supply of the TEMAH gas. Furthermore, pressure inside the process chamber 2 is 50-100 Pa which is the same as in the supply of the TEMAH gas. Due to the supply of O₂, the surface reaction occurs between the TEMAH gas and O₃ on the basic layer of the wafer 31, and the HfO₂ film is formed on the wafer 31.

(Step 4)

In the step 4, after the film formation, the second valve 59 and the fourth valve 63 are closed, and the inside of the process chamber 2 is vacuum-exhausted by the vacuum pump 68. O₃ remaining after contribution to the film formation is eliminated. Furthermore, in this case, if inert gas, for example N₂ used as the carrier gas, is supplied into the substrate process chamber 2, the effect of eliminating the remaining O₃ from the process chamber 2 is further enhanced.

The above-described steps 1 to 4 are set as one cycle, and this cycle is repeated a plurality of number of times to form the HfO₂ film having a predetermined thickness on the wafer 31.

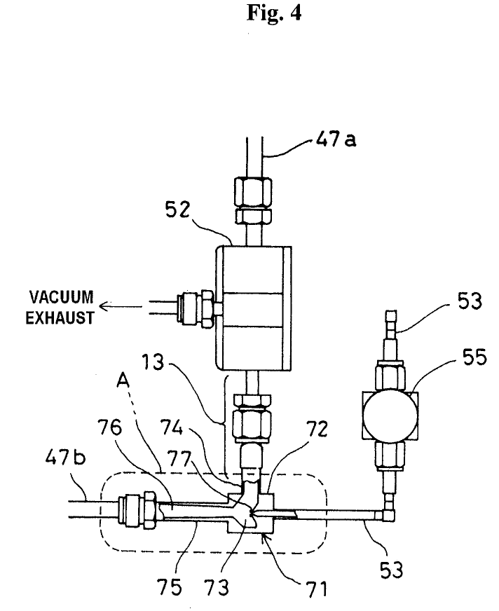

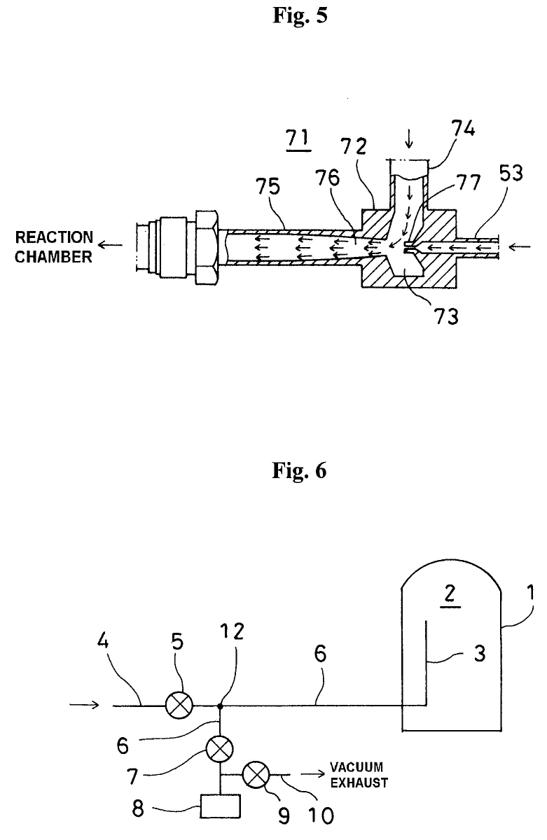

Next, explanation will be given on the joint part of the process gas supply pipe and the purge gas (carrier gas) supply pipe in the present invention, for example, the joint part 71 of the first gas supply pipe 47 and the first carrier gas supply pipe 53 with reference to FIG. 4 and FIG. 5.

At the inside of the joint block 72, a diffusion chamber 73 is formed. A first connecting pipe 74 communicates with the diffusion chamber 73, and a second connecting pipe 75 perpendicular to the first connecting pipe 74 communicates with the diffusion chamber 73. A first gas supply pipe 47a extending from the evaporator 51 is connected to the first connecting pipe 74, and a first gas supply pipe 47b directed toward the first nozzle 56 is connected to the second connecting pipe 75.

A flow path 76 formed inside the second connecting pipe 75 has a diameter which is small at the opening communicating with the diffusion chamber 73 and is gradually increasing toward the downstream side (reaction tube side) so that it has the same inner diameter as that of the first gas supply pipe 47b.

Furthermore, the first carrier gas supply pipe 53 arranged to be coaxial with the first gas supply pipe 47b communicates with the joint block 72, and a flow rate diaphragm 77 protruding to the diffusion chamber 73 is formed at the front end of the first carrier gas supply pipe 53. A flow path diameter penetrating the flow rate diaphragm 77 is sufficiently smaller than that of the inner diameter of the first carrier gas supply pipe 53, and the flow path diameter is selected so that the flow rate diaphragm 77 can exert the sufficient joint effect with respect to the fluid circulating through the first gas supply holes 57.

Furthermore, the front end of the flow rate diaphragm 77 and the opening of the flow path 76 are formed at an appropriate interval. The interval is set so that ambient gas can be effectively sucked by the depressurization when the gas from the first carrier gas supply pipe 53 is sprayed from the flow rate diaphragm 77.

However, the joint block 72 constitutes a diffuser which uses the gas flowing through the first carrier gas supply pipe 53, that is, the purge gas, as a working fluid.

The operation of the joint block 72 will be described hereinafter.

First, explanation will be given on the case where the first valve 52 is closed and the first gas supply pipe 47 is purged.

When the purge gas is supplied from the first carrier gas supply pipe 53, the purge gas is sprayed into the diffusion chamber 73 at high speed by the flow rate diaphragm 77. Thus, the purge gas is rapidly expanded and depressurized and are exhausted to the first gas supply pipe 47b through the flow path 76.

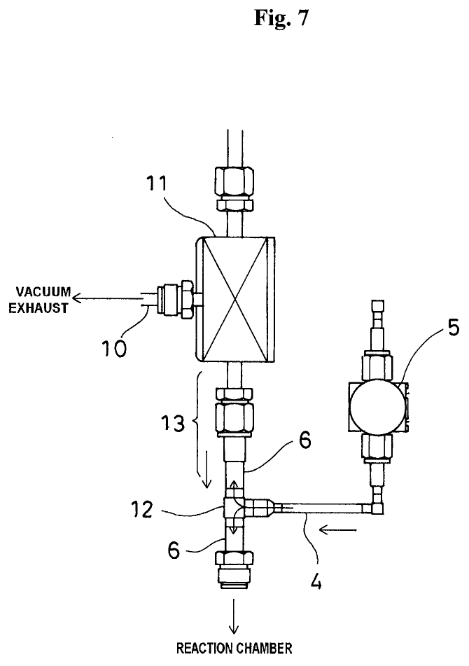

Due to the depressurization in the diffusion chamber 73, the residual process remaining in the space (dead space 13 in FIG. 7) between the joint block 72 and the first valve 52 is sucked and exhausted from the first gas supply pipe 47b together with the purge gas. Therefore, the cause of particles is eliminated.

Next, explanation will be given on the case of supplying the process gas. In this case, the purge gas acts as the carrier gas.

The first valve 52 is opened, and the evaporated process gas is supplied to the first nozzle 56 through the first gas supply pipe 47. The purge gas is sprayed to the diffusion chamber 73 through the flow rate diaphragm 77 and depressurizes the diffusion chamber 73 as described above. For this reason, the process gas is sucked from the first gas supply pipe 47. Therefore, the joint block 72 acts as a suction pump with respect to the first gas supply pipe 47 and enhances the evaporation efficiency by depressurizing the evaporation chamber of the evaporator 51. Furthermore, since the pressure loss of the pipe is compensated, the pipe distance from the evaporator 51 to the process chamber 2 can be lengthened and the limitations of design can be reduced.

Moreover, the first gas supply pipe 47b and the first carrier gas supply pipe 53 need not be perpendicular to each other, and may be inclined to communicate with the diffusion chamber 73. For example, the first gas supply pipe 47b has only to communicate with the diffusion chamber 73.

According to the embodiments of the present invention, the substrate processing apparatus includes a process chamber configured to accommodate a substrate, an evaporator configured to evaporate a liquid material, a process supply pipe configured to supply an evaporated gas from the evaporator into the process chamber, and a joint part at which the process gas supply pipe and a purge gas supply pipe are joined. The joint part has a diffusion chamber. At the diffusion chamber, the evaporated gas from the evaporator is introduced and simultaneously the purge gas is introduced through the flow rate diaphragm installed at the front end of the purge gas supply pipe. Thus, the joint part serves as a diffuser which exhausts the process gas remaining in the process gas supply pipe, thus preventing the generation of particles, enhancing the evaporation efficiency by depressurizing the inside of the evaporator through the process gas supply pipe, and compensating the pressure loss of the pipe.

(Supplementary Note)

The present invention includes the following embodiments.

(Supplementary Note 1)

According to an embodiment of the present invention, there is provided a substrate processing apparatus, comprising: a processing chamber configured to accommodate a substrate; and a gas supply unit configured to supply gas into the process chamber, wherein the gas supply unit comprises: an evaporator configured to evaporate a liquid material; a first gas supply pipe configured to supply an evaporated gas from the evaporator into the process chamber; a second gas supply pipe configured to supply an inert gas into the process chamber; and a joint part at which the first gas supply pipe and the second gas supply pipe are joined, wherein the joint part has a diffusion chamber; a flow rate diaphragm having an inner diameter narrowing toward a direction of the diffusion chamber is installed at the front end of the downstream side of the second gas supply pipe; and the evaporated gas from the evaporator is introduced into the diffusion chamber and simultaneously the inert gas is introduced through the flow rate diaphragm installed at the front end of the second gas supply pipe.

(Supplementary Note 2)

In the substrate processing apparatus of Supplementary Note 1, it is preferable that the inner diameter of an inert gas flow path penetrating the flow rate diaphragm is smaller than the inner diameter of the second gas supply pipe.

(Supplementary Note 3)

In the substrate processing apparatus of Supplementary Note 2, it is preferable the first gas supply pipe comprises a third gas supply pipe configured to form a region connected from the evaporator to the joint part, and a fourth gas supply pipe extending from the joint part to the process chamber; a first connecting pipe communicates with the diffusion chamber; a second connecting pipe directly connected to the first connecting pipe communicates with the diffusion chamber; the third gas supply pipe is connected to the first connecting pipe; the fourth gas supply pipe is connected to the second connecting pipe; and a flow path formed inside the second connecting pipe has an inner diameter which is small at an opening communicating with the diffusion chamber and is gradually increasing toward a downstream side so that the flow path has the same inner diameter as that of the second gas supply pipe.

(Supplementary Note 4)

In the substrate processing apparatus of Supplementary Note 2, it is preferable the inert gas flowing through the second gas supply pipe, and a mixed gas of the inert gas and the evaporated gas flowing out from the joint part flow in a first direction, and the evaporated gas is introduced into the diffusion chamber in a second direction different from the first direction.

(Supplementary Note 5)

In the substrate processing apparatus of Supplementary Note 2, it is preferable that the gas supply unit comprises a fifth gas supply pipe configured to supply oxide gas or nitride gas into the process chamber, and the substrate processing apparatus comprises an exhaust unit configured to exhaust atmosphere of the inside of the process chamber, and a control unit configured to control the gas supply unit and the exhaust unit to alternately supply the evaporated gas and the oxide gas or the nitride gas to thereby form a film on the substrate.

(Supplementary Note 6)

In the substrate processing apparatus of Supplementary Note 5, wherein the liquid material comprises any one of TEMAH, TEMAZ (tetrakis(ethylmethylamino)zirconium), TiCl4, TDMAS (tetrakis(dimethyl ethylamino)silane), and TMA (trimethyl aluminum).

(Supplementary Note 7)

In the substrate processing apparatus of Supplementary Note 5, it is preferable that the film formed on the substrate comprises at least one kind of Hf atom, Zr atom, Ti atom, Si atom, and Al atom.

(Supplementary Note 8)

In the substrate processing apparatus of Supplementary Note 1, it is preferable that the first gas supply pipe comprises a third gas supply pipe configured to form a region connected from the evaporator to the joint part, and a fourth gas supply pipe extending from the joint part to the process chamber; a first connecting pipe communicates with the diffusion chamber; a second connecting pipe directly connected to the first connecting pipe communicates with the diffusion chamber; the third gas supply pipe is connected to the first connecting pipe; the fourth gas supply pipe is connected to the second connecting pipe; and a flow path formed inside the second connecting pipe has an inner diameter which is small at an opening communicating with the diffusion chamber and is gradually increasing toward a downstream side so that the flow path has the same inner diameter as that of the second gas supply pipe.

(Supplementary Note 9)

In the substrate processing apparatus of Supplementary Note 8, it is preferable that the inert gas flowing through the second gas supply pipe, and a mixed gas of the inert gas and the evaporated gas flowing out from the joint part flow in a first direction, and the evaporated gas is introduced into the diffusion chamber in a second direction different from the first direction.

(Supplementary Note 10)

In the substrate processing apparatus of Supplementary Note 8, it is preferable that the gas supply unit comprises a fifth gas supply pipe configured to supply oxide gas or nitride gas into the process chamber, and the substrate processing apparatus comprises an exhaust unit configured to exhaust atmosphere of the inside of the process chamber, and a control unit configured to control the gas supply unit and the exhaust unit to alternately supply the evaporated gas and the oxide gas or the nitride gas to thereby form a film on the substrate.

(Supplementary Note 11)

In the substrate processing apparatus of Supplementary Note 1, it is preferable that the inert gas flowing through the second gas supply pipe, and a mixed gas of the inert gas and the evaporated gas flowing out from the joint part flow in a first direction, and the evaporated gas is introduced into the diffusion chamber in a second direction different from the first direction.

(Supplementary Note 12)

In the substrate processing apparatus of Supplementary Note 11, it is preferable that the gas supply unit comprises a fifth gas supply pipe configured to supply oxide gas or nitride gas into the process chamber, and the substrate processing apparatus comprises an exhaust unit configured to exhaust atmosphere of the inside of the process chamber, and a control unit configured to control the gas supply unit and the exhaust unit to alternately supply the evaporated gas and the oxide gas or the nitride gas to thereby form a film on the substrate.

(Supplementary Note 13)

In the substrate processing apparatus of Supplementary Note 1, it is preferable that the gas supply unit comprises a fifth gas supply pipe configured to supply oxide gas or nitride gas into the process chamber, and the substrate processing apparatus comprises an exhaust unit configured to exhaust atmosphere of the inside of the process chamber, and a control unit configured to control the gas supply unit and the exhaust unit to alternately supply the evaporated gas and the oxide gas or the nitride gas to thereby form a film on the substrate.

(Supplementary Note 14)

In the substrate processing apparatus of Supplementary Note 13, it is preferable that the liquid material is a liquid material having a low vapor pressure.

(Supplementary Note 15)

In the substrate processing apparatus of Supplementary Note 13, it is preferable that the liquid material comprises any one of TEMAH, TEMAZ, TiCl4, TDMAS, and TMA.

(Supplementary Note 16)

In the substrate processing apparatus of Supplementary Note 13, it is preferable that the film formed on the substrate comprises at least one kind of Hf atom, Zr atom, Ti atom, Si atom, and Al atom.

(Supplementary Note 17)

According to another embodiment of the present invention, there is provided a substrate processing apparatus, comprising: a processing chamber configured to accommodate a substrate; and a gas supply unit configured to supply gas into the process chamber, wherein the gas supply unit comprises: a first gas supply pipe configured to supply a process gas; a second gas supply pipe configured to supply a purge gas for purging at least the first gas supply pipe; and a joint part at which the first gas supply pipe, the second gas supply pipe and the third gas supply pipe are joined at a predetermined angle, wherein the joint part includes a diffusion chamber; a diaphragm having an inner diameter narrowing toward a direction of the diffusion chamber is installed at the front end of a downstream side of the second gas supply pipe; an inner diameter of a flow path penetrating the diaphragm is smaller than that of the second gas supply pipe; the purge gas is sprayed into the diffusion chamber through the flow path and is exhausted from the third gas supply pipe while sucking a residual process gas remaining in the joint part.

(Supplementary Note 18)

In the substrate processing apparatus of Supplementary Note 17, it is preferable that the gas supply unit comprises a fourth gas supply pipe configured to supply oxide gas or nitride gas into the process chamber, and the substrate processing apparatus comprises an exhaust unit configured to exhaust atmosphere of the inside of the process chamber, and a control unit configured to control the gas supply unit and the exhaust unit to alternately supply the evaporated gas and the oxide gas or the nitride gas to thereby form a film on the substrate.

(Supplementary Note 19)

In the substrate processing apparatus of Supplementary Note 18, it is preferable that the liquid material comprises any one of TEMAH, TEMAZ, TiCl4, TDMAS, and TMA.

(Supplementary Note 20)

In the substrate processing apparatus of Supplementary Note 18, it is preferable that the film formed on the substrate comprises at least one kind of Hf atom, Zr atom, Ti atom, Si atom, and Al atom.

What is claimed is:

1. A substrate processing apparatus, comprising:
a processing chamber configured to accommodate a substrate; and
a gas supply unit configured to supply gas into the process chamber,
wherein the gas supply unit comprises:
an evaporator configured to evaporate a liquid material;
a first gas supply pipe configured to supply an evaporated gas from the evaporator into the process chamber;
a second gas supply pipe configured to supply an inert gas into the process chamber; and
a joint part at which the first gas supply pipe and the second gas supply pipe are joined,
wherein the joint part has a diffusion chamber;
a flow rate diaphragm having an inner diameter narrowing toward a direction of the diffusion chamber is installed at the front end of the downstream side of the second gas supply pipe; and
the evaporated gas from the evaporator is introduced into the diffusion chamber and simultaneously the inert gas is introduced through the flow rate diaphragm installed at the front end of the second gas supply pipe.

2. The substrate processing apparatus of claim 1, wherein the inner diameter of an inert gas flow path penetrating the flow rate diaphragm is smaller than the inner diameter of the second gas supply pipe.

3. The substrate processing apparatus of claim 2, wherein the first gas supply pipe comprises a third gas supply pipe configured to form a region connected from the evaporator to the joint part, and a fourth gas supply pipe extending from the joint part to the process chamber;
a first connecting pipe communicates with the diffusion chamber;
a second connecting pipe directly connected to the first connecting pipe communicates with the diffusion chamber;
the third gas supply pipe is connected to the first connecting pipe;
the fourth gas supply pipe is connected to the second connecting pipe; and
a flow path formed inside the second connecting pipe has an inner diameter which is small at an opening communicating with the diffusion chamber and is gradually increasing toward a downstream side so that the flow path has the same inner diameter as that of the second gas supply pipe.

4. The substrate processing apparatus of claim 2, wherein the inert gas flowing through the second gas supply pipe, and a mixed gas of the inert gas and the evaporated gas flowing out from the joint part flow in a first direction, and the evaporated gas is introduced into the diffusion chamber in a second direction different from the first direction.

5. The substrate processing apparatus of claim 2, wherein the gas supply unit comprises a fifth gas supply pipe configured to supply oxide gas or nitride gas into the process chamber, and the substrate processing apparatus comprises an exhaust unit configured to exhaust atmosphere of the inside of the process chamber, and a control unit configured to control the gas supply unit and the exhaust unit to alternately supply the evaporated gas and the oxide gas or the nitride gas to thereby form a film on the substrate.

6. The substrate processing apparatus of claim 5, wherein the liquid material comprises any one of TEMAH, TEMAZ, TiCl₄, TDMAS, and TMA.

7. The substrate processing apparatus of claim 5, wherein the film formed on the substrate comprises at least one kind of Hf atom, Zr atom, Ti atom, Si atom, and Al atom.

8. The substrate processing apparatus of claim 1, wherein the first gas supply pipe comprises a third gas supply pipe configured to form a region connected from the evaporator to the joint part, and a fourth gas supply pipe extending from the joint part to the process chamber;
a first connecting pipe communicates with the diffusion chamber;
a second connecting pipe directly connected to the first connecting pipe communicates with the diffusion chamber;
the third gas supply pipe is connected to the first connecting pipe;
the fourth gas supply pipe is connected to the second connecting pipe; and
a flow path formed inside the second connecting pipe has an inner diameter which is small at an opening communicating with the diffusion chamber and is gradually increasing toward a downstream side so that the flow path has the same inner diameter as that of the second gas supply pipe.

9. The substrate processing apparatus of claim 8, wherein the inert gas flowing through the second gas supply pipe, and a mixed gas of the inert gas and the evaporated gas flowing out from the joint part flow in a first direction, and the evaporated gas is introduced into the diffusion chamber in a second direction different from the first direction.

10. The substrate processing apparatus of claim 8, wherein the gas supply unit comprises a fifth gas supply pipe configured to supply oxide gas or nitride gas into the process chamber, and the substrate processing apparatus comprises an exhaust unit configured to exhaust atmosphere of the inside of the process chamber, and a control unit configured to control the gas supply unit and the exhaust unit to alternately supply the evaporated gas and the oxide gas or the nitride gas to thereby form a film on the substrate.

11. The substrate processing apparatus of claim 1, wherein the inert gas flowing through the second gas supply pipe, and a mixed gas of the inert gas and the evaporated gas flowing out from the joint part flow in a first direction, and the evaporated gas is introduced into the diffusion chamber in a second direction different from the first direction.

12. The substrate processing apparatus of claim 11, wherein the gas supply unit comprises a fifth gas supply pipe configured to supply oxide gas or nitride gas into the process chamber, and the substrate processing apparatus comprises an exhaust unit configured to exhaust atmosphere of the inside of the process chamber, and a control unit configured to control the gas supply unit and the exhaust unit to alternately supply the evaporated gas and the oxide gas or the nitride gas to thereby form a film on the substrate.

13. The substrate processing apparatus of claim 1, wherein the gas supply unit comprises a fifth gas supply pipe configured to supply oxide gas or nitride gas into the process chamber, and the substrate processing apparatus comprises an exhaust unit configured to exhaust atmosphere of the inside of the process chamber, and a control unit configured to control the gas supply unit and the exhaust unit to alternately supply the evaporated gas and the oxide gas or the nitride gas to thereby form a film on the substrate.

14. The substrate processing apparatus of claim 13, wherein the liquid material is a liquid material having a low vapor pressure.

15. The substrate processing apparatus of claim 13, wherein the liquid material comprises any one of TEMAH, TEMAZ, TiCl₄, TDMAS, and TMA.

16. The substrate processing apparatus of claim 13, wherein the film formed on the substrate comprises at least one kind of Hf atom, Zr atom, Ti atom, Si atom, and Al atom.

17. A substrate processing apparatus, comprising:
a processing chamber configured to accommodate a substrate; and
a gas supply unit configured to supply gas into the process chamber,
wherein the gas supply unit comprises:
a first gas supply pipe configured to supply a process gas;
a second gas supply pipe configured to supply a purge gas for purging at least the first gas supply pipe; and
a joint part at which the first gas supply pipe, the second gas supply pipe and the third gas supply pipe are joined at a predetermined angle,
wherein the joint part includes a diffusion chamber;
a diaphragm having an inner diameter narrowing toward a direction of the diffusion chamber is installed at the front end of a downstream side of the second gas supply pipe;
an inner diameter of a flow path penetrating the diaphragm is smaller than that of the second gas supply pipe; and
the purge gas is sprayed into the diffusion chamber through the flow path and is exhausted from the third gas supply pipe while sucking a residual process gas remaining in the joint part.

18. The substrate processing apparatus of claim 17, wherein the gas supply unit comprises a fourth gas supply pipe configured to supply oxide gas or nitride gas into the process chamber, and the substrate processing apparatus comprises an exhaust unit configured to exhaust atmosphere of the inside of the process chamber, and a control unit configured to control the gas supply unit and the exhaust unit to alternately supply the evaporated gas and the oxide gas or the nitride gas to thereby form a film on the substrate.

19. The substrate processing apparatus of claim 18, wherein the liquid material comprises any one of TEMAH, TEMAZ, TiCl₄, TDMAS, and TMA.

20. The substrate processing apparatus of claim 18, wherein the film formed on the substrate comprises at least one kind of Hf atom, Zr atom, Ti atom, Si atom, and Al atom.
